(19) United States
(12) Patent Application Publication
(10) Pub. No.: US 2026/0211316 A1
(43) Pub. Date: Jul. 23, 2026

(54) TEMPLATE, IMPRINT METHOD, AND METHOD OF MANUFACTURING SEMICONDUCTOR DEVICE

(71) Applicant: Kioxia Corporation, Tokyo (JP)

(72) Inventors: Kazuya Fukuhara, Yokkaichi Mie (JP); Masaki Mitsuyasu, Kuwana Mie (JP); Masaki Kubo, Yokkaichi Mie (JP)

(73) Assignee: Kioxia Corporation, Tokyo (JP)

(21) Appl. No.: 19/238,923

(22) Filed: Jun. 16, 2025

(30) Foreign Application Priority Data
Jan. 22, 2025 (JP) 2025-009032

(51) Int. Cl. G03F 7/00; H01L 21/308

(52) U.S. Cl. CPC G03F 7/0002; H10P 50/695

(57) ABSTRACT

A template includes a mesa including: a pattern surface having an imprint pattern; a first face along a first end in a first direction, having a first height to an uppermost face; a second face along a second end in a second direction, having a second height to the uppermost face; a third face along a third end opposite the second end in the second direction, having a third height greater than each of the first and second heights to the uppermost face; a fourth face along a fourth end opposite the first end in the first direction, having a fourth height greater than each of the first and second heights the uppermost face; and a fifth face along a first corner adjacent to each of the third and fourth ends, having a fifth height greater than each of the third and fourth heights to the uppermost face.

### CROSS-REFERENCE TO RELATED APPLICATIONS

This application is based upon and claims the benefit of priority from Japanese Patent Application No. 2025-009032, filed on Jan. 22, 2025; the entire contents of which are incorporated herein by reference.

### FIELD

Embodiments relate to a template, an imprint method, and a method of manufacturing a semiconductor device.

### BACKGROUND

A known example method of manufacturing a semiconductor device uses a technique of forming a fine pattern using nanoimprint lithography (NIL).

### BRIEF DESCRIPTION OF THE DRAWINGS

FIG. 1 is a schematic view for explaining a structure example of a template.

FIG. 2 is a schematic view for explaining the structure example of the template.

FIG. 3 is a schematic view for explaining an example of an imprint method.

FIG. 4 is a schematic view for explaining the example of the imprint method.

FIG. 5 is a plan schematic view for explaining a structure example of a surface of a mesa MS.

FIG. 6 is a plan schematic view for explaining another structure example of the surface of the mesa MS.

FIG. 7 is a cross-sectional schematic view of a part of the mesa MS in a Z-axis direction.

FIG. 8 is a cross-sectional schematic view of a part of the mesa MS in the Z-axis direction.

FIG. 9 is a cross-sectional schematic view of a part of the mesa MS in the Z-axis direction.

FIG. 10 is a cross-sectional schematic view of a part of the mesa MS in the Z-axis direction.

FIG. 11 is a cross-sectional schematic view of a part of the mesa MS in the Z-axis direction.

FIG. 12 is a schematic view for explaining an example of an imprint method.

FIG. 13 is a schematic view for explaining an example of imprinting on a shot area 110a.

FIG. 14 is a schematic view for explaining the example of imprinting on the shot area 110a.

FIG. 15 is a schematic view for explaining the example of imprinting on the shot area 110a.

FIG. 16 is a schematic view for explaining the example of imprinting on the shot area 110a.

FIG. 17 is a schematic view for explaining an example of imprinting on a shot area 110b.

FIG. 18 is a schematic view for explaining the example of imprinting on the shot area 110b.

FIG. 19 is a schematic view for explaining the example of imprinting on the shot area 110b.

FIG. 20 is a schematic view for explaining the example of imprinting on the shot area 110b.

FIG. 21 is a schematic view for explaining an example of imprinting on a shot area 110c.

FIG. 22 is a schematic view for explaining the example of imprinting on the shot area 110c.

FIG. 23 is a schematic view for explaining the example of imprinting on the shot area 110c.

FIG. 24 is a schematic view for explaining the example of imprinting on the shot area 110c.

FIG. 25 is a schematic view for explaining an example of imprinting on a shot area 110d.

FIG. 26 is a schematic view for explaining the example of imprinting on the shot area 110d.

FIG. 27 is a schematic view for explaining the example of imprinting on the shot area 110d.

FIG. 28 is a schematic view for explaining the example of imprinting on the shot area 110d.

FIG. 29 is a cross-sectional schematic view of a part of the mesa MS in the Z-axis direction in a first further example.

FIG. 30 is a cross-sectional schematic view of a part of the mesa MS in the Z-axis direction in the first further example.

FIG. 31 is a cross-sectional schematic view of a part of the mesa MS in the Z-axis direction in the first further example.

FIG. 32 is a cross-sectional schematic view of a part of the mesa MS in the Z-axis direction in the first further example.

FIG. 33 is a cross-sectional schematic view of a part of the mesa MS in the Z-axis direction in the first further example.

FIG. 34 is a schematic view for explaining an example of imprinting on the shot area 110a in the first further example.

FIG. 35 is a schematic view for explaining the example of imprinting on the shot area 110a in the first further example.

FIG. 36 is a schematic view for explaining the example of imprinting on the shot area 110a in the first further example.

FIG. 37 is a schematic view for explaining an example of imprinting on the shot area 110b in the first further example.

FIG. 38 is a schematic view for explaining the example of imprinting on the shot area 110b in the first further example.

FIG. 39 is a schematic view for explaining the example of imprinting on the shot area 110b in the first further example.

FIG. 40 is a schematic view for explaining an example of imprinting on the shot area 110c in the first further example.

FIG. 41 is a schematic view for explaining the example of imprinting on the shot area 110c in the first further example.

FIG. 42 is a schematic view for explaining the example of imprinting on the shot area 110c in the first further example.

FIG. 43 is a schematic view for explaining an example of imprinting on the shot area 110d in the first further example.

FIG. 44 is a schematic view for explaining the example of imprinting on the shot area 110d in the first further example.

FIG. 45 is a schematic view for explaining the example of imprinting on the shot area 110d in the first further example.

FIG. 46 is a plan schematic view for explaining a structure example of the surface of the mesa MS in a second further example.

FIG. 47 is a plan schematic view for explaining another structure example of the surface of the mesa MS in the second further example.

FIG. 48 is a schematic view for explaining an example of imprinting on the shot area 110d.

FIG. 49 is a schematic view for explaining the example of imprinting on the shot area 110d.

FIG. 50 is a schematic view for explaining the example of imprinting on the shot area 110d.

FIG. 51 is a schematic view for explaining the example of imprinting on the shot area 110d.

FIG. 52 is a plan schematic view for explaining a structure example of the surface of the mesa MS.

FIG. 53 is a schematic view for explaining an example of imprinting on the shot area 110a in a third further example.

FIG. 54 is a schematic view for explaining the example of imprinting on the shot area 110a in the third further example.

FIG. 55 is a schematic view for explaining the example of imprinting on the shot area 110a in the third further example.

FIG. 56 is a schematic view for explaining an example of imprinting on the shot area 110b in the third further example.

FIG. 57 is a schematic view for explaining the example of imprinting on the shot area 110b in the third further example.

FIG. 58 is a schematic view for explaining the example of imprinting on the shot area 110b in the third further example.

FIG. 59 is a schematic view for explaining an example of imprinting on the shot area 110c in the third further example.

FIG. 60 is a schematic view for explaining the example of imprinting on the shot area 110c in the third further example.

FIG. 61 is a schematic view for explaining the example of imprinting on the shot area 110c in the third further example.

FIG. 62 is a schematic view for explaining an example of imprinting on the shot area 110d in the third further example.

FIG. 63 is a schematic view for explaining the example of imprinting on the shot area 110d in the third further example.

FIG. 64 is a schematic view for explaining the example of imprinting on the shot area 110d in the third further example.

FIG. 65 is a cross-sectional schematic view for explaining an example of a method of manufacturing a semiconductor device.

FIG. 66 is a cross-sectional schematic view for explaining the example of the method.

### DETAILED DESCRIPTION

A template of an embodiment includes a mesa. The mesa includes a pattern surface including an imprint pattern; a first face provided along a first end of the mesa in a first direction, the first face having a first height relative to an uppermost face of the pattern surface; a second face provided along a second end of the mesa in a second direction perpendicular to the first direction, the second face having a second height relative to the uppermost face; a third face provided along a third end of the mesa in the second direction, the third end being opposite the second end, the third face having a third height greater than each of the first height and the second height relative to the uppermost face; a fourth face provided along a fourth end of the mesa in the first direction, the fourth end being opposite the first end, and the fourth face having a fourth height greater than each of the first height and the second height relative to the uppermost face; and a fifth face provided along a first corner of the mesa, the first corner being adjacent to each of the third end and the fourth end, and the fifth face having a fifth height greater than each of the third height and the fourth height relative to the uppermost face.

Embodiments will be hereinafter explained with reference to the drawings. A relation between the thickness and planar dimension of each of components illustrated in the drawings, a thickness ratio among the components, and so on may be different from actual ones. Further, in the embodiments, substantially the same components are denoted by the same reference signs, and an explanation thereof is omitted as appropriate.

### (Imprint Method)

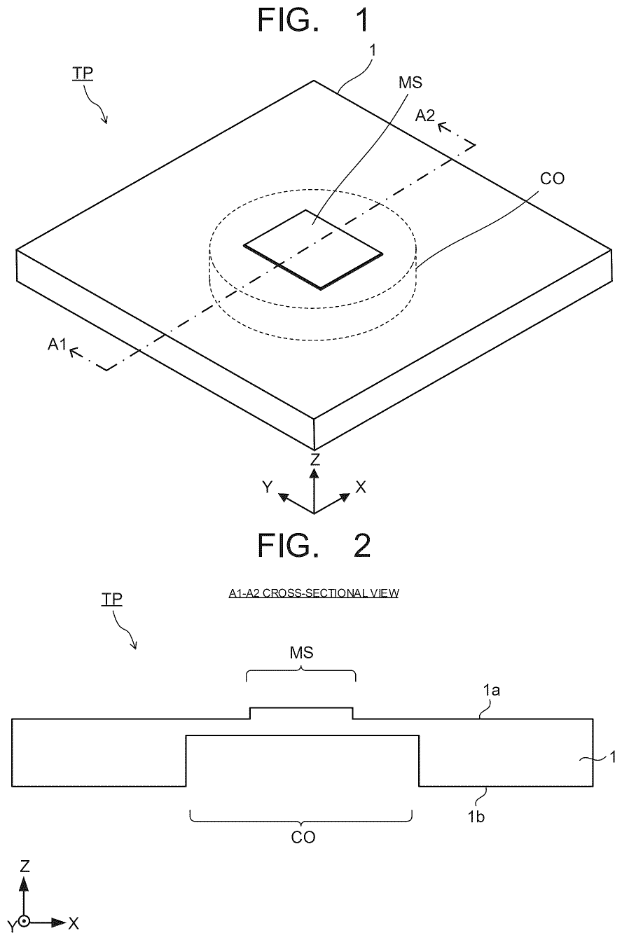

FIG. 1 and FIG. 2 are schematic views for explaining a structure example of a template used in a pattern-forming method using NIL (hereinafter referred to as an imprint method). FIG. 1 is a perspective schematic view illustrating the structure example of a template TP. FIG. 2 is a cross-sectional schematic view illustrating the structure example of the template TP and illustrates a part of a cross-section at a line segment A1-A2 illustrated in FIG. 1. FIG. 1 and FIG. 2 illustrate X, Y, and Z axes of the template TP. The X, Y, and Z axes extend perpendicular to each other. The Z-axis direction is a thickness direction of the template TP.

The template TP includes a substrate 1 having a surface 1a including a mesa MS and a surface 1b including a recess CO. The mesa MS has an imprint pattern such as a device pattern. The imprint pattern has at least one of a depression and a protrusion. The substrate 1 can transmit light. The substrate 1 can be formed using, for example, quartz glass.

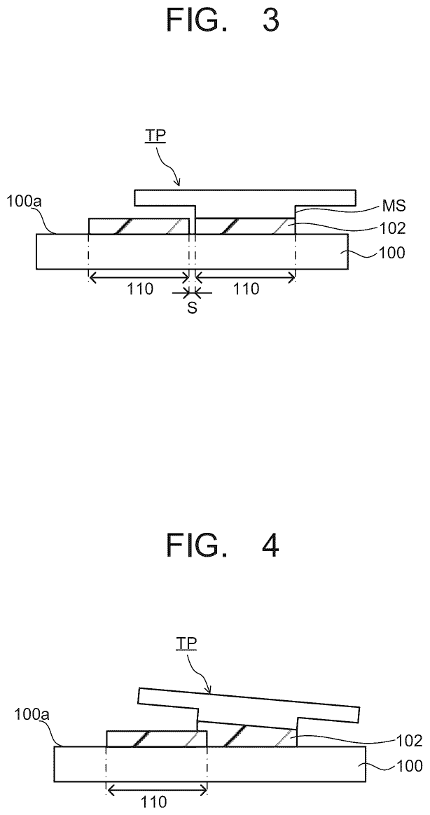

FIG. 3 and FIG. 4 are schematic views for explaining examples of the imprint method. In the imprint method, an imprint material layer 102 such as an ultraviolet curable resin formed on a surface of an object 100 is formed by pressing the template TP onto the imprint material layer 102, bringing the imprint pattern of the mesa MS into contact with a surface of the imprint material layer 102, and the imprint pattern is transferred to the imprint material layer 102 by irradiating light such as ultraviolet light through the template TP to cure the imprint material layer 102. The template TP is then separated from the imprint material layer 102.

Examples of the object 100 include a processible film, which is a stack formed by stacking a plurality of films on a substrate such as a silicon wafer. The plurality of the films include a conductive film or/and an insulating film. Examples of the stack include a device wafer (semiconductor substrate) in the middle of manufacturing a semiconductor device. Examples of the semiconductor device include a semiconductor memory device such as a NAND flash memory, an electrical device having a microstructure such as a microelectromechanical system (MEMS), and a magnetic recording medium. A configuration of the object 100 is not limited to the above configuration.

The object 100 has a surface 100a that includes a shot area 110. The shot area 110 is a unit area to which patterns are transferred all at once by pressing the template TP against the imprint material layer 102 in one imprint.

The imprint material layer 102 can be formed by applying an imprint material to the shot area 110 using, for example, an ink-jet method. The imprint material contains, for example, a light-curing resin such as a photoresist.

As illustrated in FIG. 3, when imprinting is performed on a plurality of shot areas 110, it is necessary to form a space S between adjacent shot areas 110. When the space S exists, for example, a portion overlapping the space S is etched more than necessary when an imprint material layer is used as an etching mask to etch the object 100, and there is a problem that conductive layers such as wiring in the object 100 are exposed unnecessarily. Therefore, the space S should be as small as possible. However, when imprinting is performed on the adjacent shot areas 110 without forming the space S, there is a problem that the template TP and another imprint material layer 102 get on a cured imprint material layer 102 on the shot area 110 where imprinting was performed earlier and they are in contact with each other as illustrated in FIG. 4. This causes the template TP to tilt, resulting in damage to the template TP, pattern formation defects, and other problems.

In contrast, the imprint method of this embodiment uses the template TP having a plurality of faces with different heights on a peripheral edge of the mesa MS to perform imprinting. The imprint method of this embodiment is explained below.

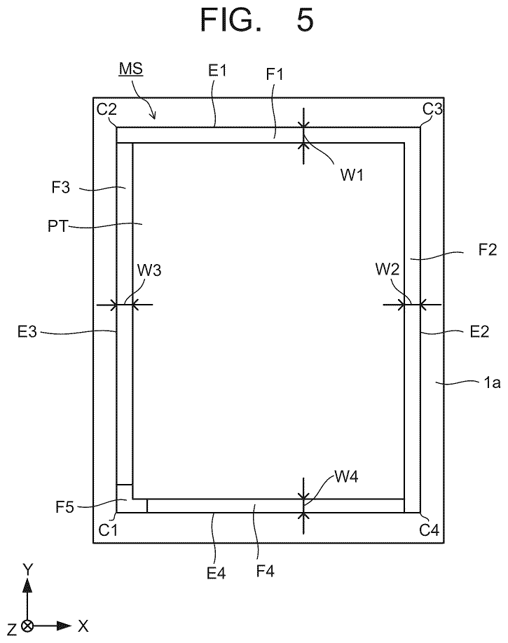

FIG. 5 is a plan schematic view for explaining a structure example of a surface of the mesa MS. FIG. 5 illustrates an X-axis direction, Y-axis direction, and Z-axis direction of the mesa MS. The X-, Y-, and Z-axis directions are perpendicular to each other. The Z-axis direction is a thickness direction of the template TP. In FIG. 5, an outer portion of the surface 1a of the template is not illustrated.

The surface of the mesa MS includes a corner C1, a corner C2, a corner C3, a corner C4, an end E1, an end E2, an end E3, and an end E4.

The corners C1, C2, C3, and C4 are located at four corners of the surface of the mesa MS. The corners C1, C2, C3, and C4 may be chamfered diagonally or rounded relative to the X-and Y-axis directions. The corner C1 is adjacent to each of one end of the end E3 and one end of the end E4. The corner C2 is adjacent to each of one end of the end E1 and the other end of the end E3. The corner C3 is adjacent to each of the other end of the end E1 and one end of the end E2. The corner C4 is adjacent to each of the other end of the end E2 and the other end of the end E4.

The ends E1, E2, E3, and E4 are located on the peripheral edge of the surface of the mesa MS. The end E1 is located at one end of the mesa MS in the Y-axis direction. The end E1 extends, for example, from the corner C2 to the corner C3. The end E2 is located at one end of the mesa MS in the X-axis direction. The end E2 extends, for example, from the corner C3 to the corner C4. The end E3 is located at the other end of the mesa MS (opposite the end E2) in the X-axis direction. The end E3 extends, for example, from the corner C1 to the corner C2. The end E4 is located at the other end of the mesa MS (opposite the end E1) in the Y-axis direction. The end E4 extends, for example, from the corner C1 to the corner C4.

Furthermore, the surface of the mesa MS has a pattern surface PT, a face F1, a face F2, a face F3, a face F4, and a face F5. The faces F1, F2, F3, F4, and F5 are provided around the pattern surface PT. The pattern surface PT may be surrounded by the faces F1, F2, F3, F4, and F5. A peripheral edge of the pattern surface PT may have a kerf area that does not have an imprint pattern.

The pattern surface PT includes imprint patterns that are transferred by the imprint method. The number, location, and shape of the imprint patterns are not limited. The imprint pattern can be formed, for example, by forming at least one of a depression that depresses in the Z-axis direction and a protrusion that protrudes in the Z-axis direction.

The face F1 is provided along the end E1. The face F1 extends along the end E1 from the corner C2 to the corner C3 between the corners C2 and C3. A width W1 of the face F1 in the Y-axis direction is not limited, but is, for example, 0.1 μm or more and 10 μm or less.

The face F2 is provided along the end E2. The face F2 extends along the end E2 from the corner C3 to the corner C4 between the corners C3 and C4. The face F2 forms one continuous plane together with the face F1. A width W2 of the face F2 in the X-axis direction is not limited, but is, for example, 0.1 μm or more and 10 μm or less.

The face F3 is provided along the end E3. The face F3 extends along the end E3 from one end of the face F1 to one end of the face F5 between the corners C1 and C2. A width W3 of the face F3 in the X-axis direction is not limited, but is, for example, 0.1 μm or more and 10 μm or less.

The face F4 is provided along the end E4. The face F4 extends along the end E4 from one end of the face F2 to the other end of the face F5 between the corners C1 and C4. A width W4 of the face F4 in the Y-axis direction is not limited, but is, for example, 0.1 μm or more and 10 μm or less.

The face F5 is provided along the corner C1. The face F5 extends along the end E3 from the corner C1 to one end of the face F3 and extends along the end E4 from the corner C1 to one end of the face F4. The face F5 has each of the width W3 and the width W4.

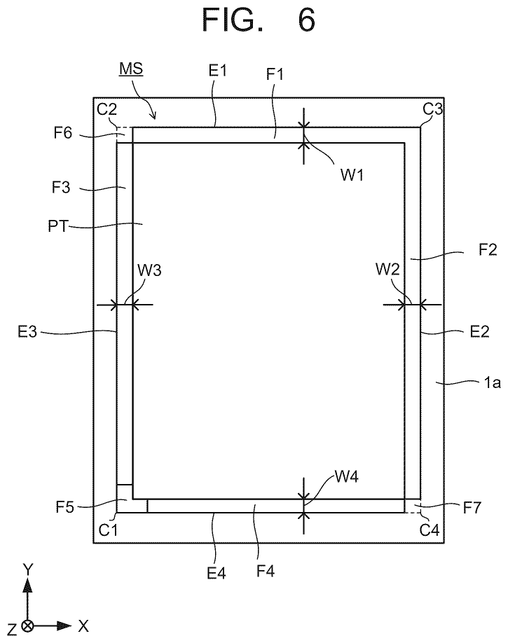

The structure of the surface of the mesa MS is not limited to the structure illustrated in FIG. 5. FIG. 6 is a plan schematic view for explaining another structure example of the surface of the mesa MS. FIG. 6 differs from FIG. 5 in that it has a face F6 near the corner C2 and a face F7 near the corner C4. The following is an explanation of portions that differ from FIG. 5, and the explanation of FIG. 5 can be used as appropriate for the other portions.

The face F1 extends along the end E1 from one end of the face F6 to the corner C3 between the corners C2 and C3.

The face F2 extends along the end E2 from the corner C3 to one end of the face F7 between the corners C3 and C4.

The face F3 extends along the end E3 from one end of the face F5 to the other end of the face F6 between the corners C1 and C2.

The face F4 extends along the end E4 from the other end of the face F5 to the other end of the face F7 between the corners C1 and C4.

The face F6 is provided along the corner C2. The face F6 extends along the end E1 from the corner C2 to one end of the face F1 and extends along the end E3 from the corner C2 to the other end of the face F3.

The face F7 is provided along the corner C4. The face F7 extends along the end E2 from the corner C4 to one end of the face F2 and extends along the end E4 from the corner C4 to the other end of the face F4.

FIG. 7 to FIG. 11 are enlarged views each illustrating a part of the pattern of the mesa MS illustrated in FIG. 2, where the Z direction is opposite to FIG. 2. FIG. 7 is a cross-sectional schematic view of a part of the mesa MS in the Z-axis direction. FIG. 7 illustrates the face F1. The face F1 has a height H1 relative to a face TS of the pattern surface PT. The face TS is, for example, an uppermost face of the pattern surface PT in FIG. 2. A height of the face F1 should be the same as a height of the face TS or higher. The height H1 may be smaller than a height of a face BS provided in a depression D of the pattern surface PT relative to the face TS. The face BS is, for example, a lowermost face of the pattern surface PT in FIG. 2. A height of the depression D is not limited, but is, for example, 30 nm or more and 100 nm or less. The depression D forms an imprint pattern after transfer.

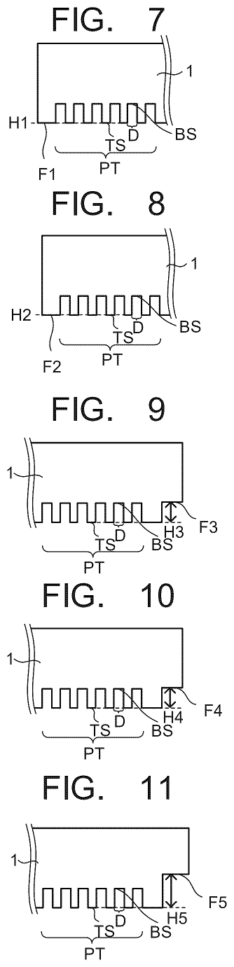

FIG. 8 is a cross-sectional schematic view of a part of the mesa MS in the Z-axis direction. FIG. 8 illustrates the face F2. The face F2 has a height H2 relative to the face TS. A height of the face F2 should be the same as a height of the face TS or higher. The height H2 may be smaller than the height of the face BS provided in the depression D of the pattern surface PT relative to the face TS. The height H2 is, for example, the same height as the height H1.

FIG. 9 is a cross-sectional schematic view of a part of the mesa MS in the Z-axis direction. FIG. 9 illustrates the face F3. The face F3 has a height H3 relative to the face TS. The height H3 is greater than the height of the face TS. A height of the face F3 may be as same as a height of the face BS, or greater than the height of the face BS relative to the face TS.

FIG. 10 is a cross-sectional schematic view of a part of the mesa MS in the Z-axis direction. FIG. 10 illustrates the face F4. The face F4 has a height H4 relative to the face TS. The height H4 is greater than the height of the face TS. A height of the face F4 may be as same as a height of the face BS, or greater than the height of the face BS relative to the face TS. The height H4 is, for example, the same height as the height H3.

FIG. 11 is a cross-sectional schematic view of a part of the mesa MS in the Z-axis direction. FIG. 11 illustrates the face F5. The face F5 has a height H5 relative to the face TS. The height H5 is greater than the height of the face TS and greater than each of the height H3 and the height H4. The height H5 may be greater than that of the face BS relative to the face TS.

The pattern surface PT, the faces F1, F2, F3, F4, and F5 can be formed, for example, by dry etching the substrate using a mask in a thickness direction of.

When the surface of the mesa MS has the structure illustrated in FIG. 6, the respective heights of the faces F6 and F7 are the same height as the height of the face TS.

FIG. 12 is a schematic view for explaining an example of the imprint method using the template TP with the mesa MS illustrated in FIG. 5. FIG. 12 illustrates the template TP and a part of the surface 100a of the object 100 to be imprinted.

The surface 100a has a plurality of shot areas 110, including a shot area 110a, a shot area 110b, a shot area 110c, and a shot area 110d. The plurality of shot areas 110 are arranged along the surface 100a. The “shot area” is a processing unit to which a pattern is transferred in one imprint. The number of shot areas is not limited to the number illustrated in FIG. 12.

The shot area 110b is adjacent to the shot area 110a in the X-axis direction. The shot area 110c is adjacent to the shot area 110a in the Y-axis direction. The shot area 110d is adjacent to the shot area 110b in the Y-axis direction and adjacent to the shot area 110c in the X-axis direction. The shot area 110a, the shot area 110b, the shot area 110c, and the shot area 110d have space S among them. A width of the space S is not limited, but is, for example, 1 μm or more and 10 μm or less.

In NIL, an imprint apparatus is used to perform imprinting on, for example, the shot area 110a, the shot area 110b, the shot area 110c, and the shot area 110d, in that order. The template TP is used so that the surface of the mesa MS illustrated in FIG. 5 faces each of the shot area 110a, shot area 110b, shot area 110c, and shot area 110d.

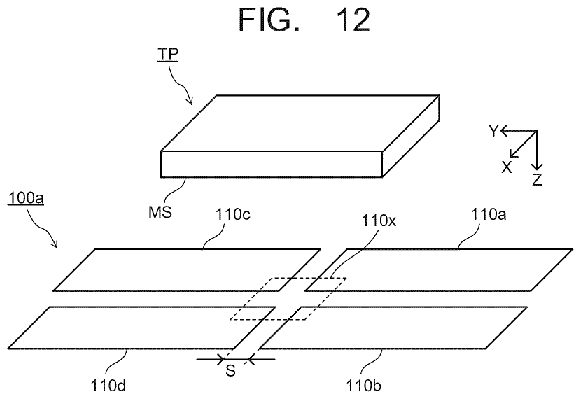

First, imprinting is performed on the shot area 110a. FIG. 13, FIG. 14, FIG. 15, and FIG. 16 are schematic views for explaining an example of imprinting on the shot area 110a. FIG. 13 schematically illustrates an upper surface of an intersection 110x among the shot area 110a, shot area 110b, shot area 110c, and shot area 110d. FIG. 14 schematically illustrates an X-Z cross-section of the intersection 110x at a line segment A1-A2 in FIG. 13. FIG. 15 schematically illustrates a Y-Z cross-section of the intersection 110x at a line segment B1-B2 in FIG. 13. FIG. 16 schematically illustrates an example of a three-dimensional shape of a part of an imprint material layer 102a cured in the shot area 110a.

In the example of imprinting on the shot area 110a, the template TP is pressed against the imprint material layer 102a formed in the shot area 110a so that the faces F1 and F2 overlap the space S viewed from the Z-axis direction, the pattern surface PT is brought into contact with the imprint material layer 102a to form the imprint material layer 102a, and the template TP is separated after the imprint material layer 102a is cured.

In FIG. 14, the imprint material layer 102a is in contact with the face F1 and formed according to the height H1. In FIG. 15, the imprint material layer 102a is in contact with the face F2 and formed according to the height H2. This allows a cured layer of the imprint material layer 102a to be formed. When using the template TP with the surface illustrated in FIG. 6, for example, a cured layer of the imprint material layer 102a with the shape illustrated in FIG. 16 can be formed. A pattern corresponding to the depression D of the template TP, which is not illustrated in the figure, is transferred to a rectangular protrusion of the imprint material layer 102a in FIG. 16.

Note that FIG. 13, FIG. 14, and FIG. 15 are illustrated so that an end portion of the face F1 in the Y-axis direction overlaps an end portion of the space S between the shot area 110a and the shot area 110c in the Y-axis direction viewed from the Z-axis direction, and an end portion of the face F2 in the X-axis direction overlaps the end portion of the space S between the shot area 110a and the shot area 110b in the X-axis direction viewed from the Z-axis direction. However, the face F1 only needs to overlap at least a part of the space S between the shot area 110a and the shot area 110c viewed from the Z-axis direction, and the face F2 only needs to overlap at least a part of the space S between the shot area 110a and the shot area 110b viewed from the Z-axis direction.

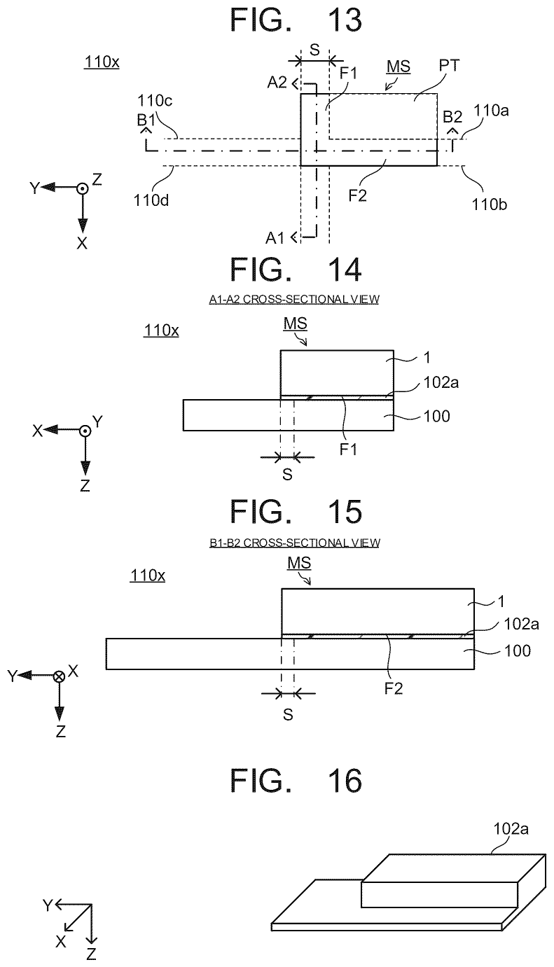

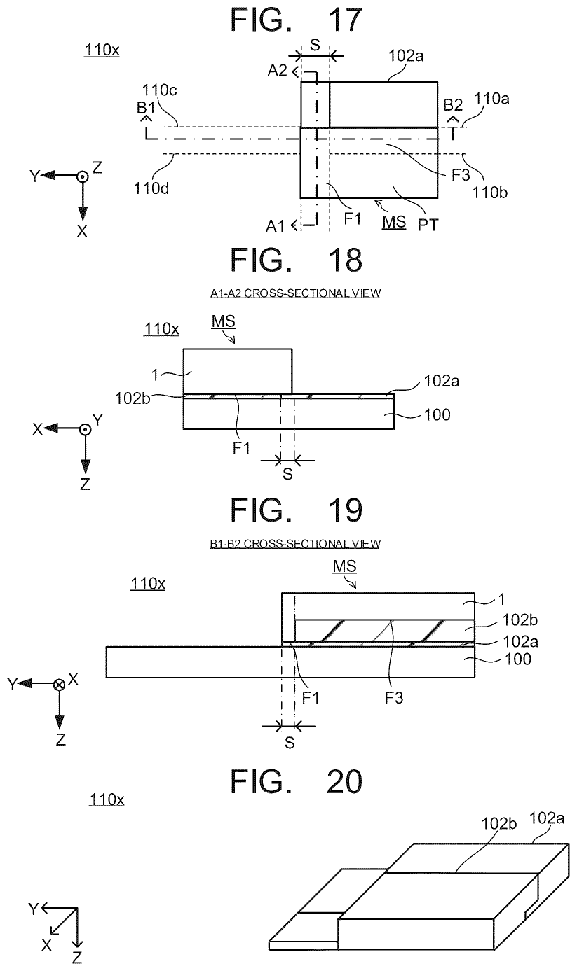

Next, imprinting is performed on the shot area 110b. FIG. 17, FIG. 18, FIG. 19, and FIG. 20 are schematic views for explaining an example of imprinting on the shot area 110b. FIG. 17 schematically illustrates the upper surface of the intersection 110x. FIG. 18 schematically illustrates an X-Z cross-section of the intersection 110x at a line segment A1-A2 in FIG. 17. FIG. 19 schematically illustrates a Y-Z cross-section of the intersection 110x at a line segment B1-B2 in FIG. 17. FIG. 20 schematically illustrates an example of a three-dimensional shape of a part of the cured imprint material layer 102b.

In the example of imprinting on the shot area 110b, the template TP is pressed against the imprint material layer 102b formed in the shot area 110b so that the faces F1 and F3 overlap the space S in the Z-axis direction, the pattern surface PT is brought into contact with the imprint material layer 102b to form the imprint material layer 102b, and the template TP is separated after the imprint material layer 102b is cured.

In FIG. 18, the imprint material layer 102b is in contact with the face F1 and formed according to the height H1, but a part of the cured imprint material layer 102a is also in contact with the face F1, so a portion of the imprint material layer 102b having the same height as the imprint material layer 102a is not stacked on a part of the imprint material layer 102a. In FIG. 19, a part of the imprint material layer 102b is in contact with the face F1 and formed according to the height H1, so the portion of the imprint material layer 102b having the same height as the imprint material layer 102a is not stacked on a part of the imprint material layer 102a. Another part of the imprint material layer 102b is in contact with the face F3 and formed according to the height H3. Thus, a part of the imprint material layer 102b is stacked on a part of the imprint material layer 102a in the space S. This allows a cured layer of the imprint material layer 102b to be formed. When the template TP with the surface illustrated in FIG. 6 is used, for example, a cured layer of the imprint material layer 102b with the shape illustrated in FIG. 20 can be formed. A pattern corresponding to the depression D of the template TP, which is not illustrated in the figure, is transferred to a rectangular protrusion of the imprint material layer 102b in FIG. 20.

Note that FIG. 17, FIG. 18, and FIG. 19 are illustrated so that the end portion of the face F1 in the Y-axis direction overlaps the end portion of the space S between the shot area 110b and the shot area 110d in the Y-axis direction viewed from the Z-axis direction, and the end portion of the face F3 in the X-axis direction overlaps the end portion of the space S between the shot area 110a and the shot area 110b in the X-axis direction viewed from the Z-axis direction. However, the face F1 only needs to overlap at least a part of the space S between the shot area 110b and the shot area 110d viewed from the Z-axis direction, and the face F3 only needs to overlap at least a part of the space S between the shot area 110a and the shot area 110b viewed from the Z-axis direction.

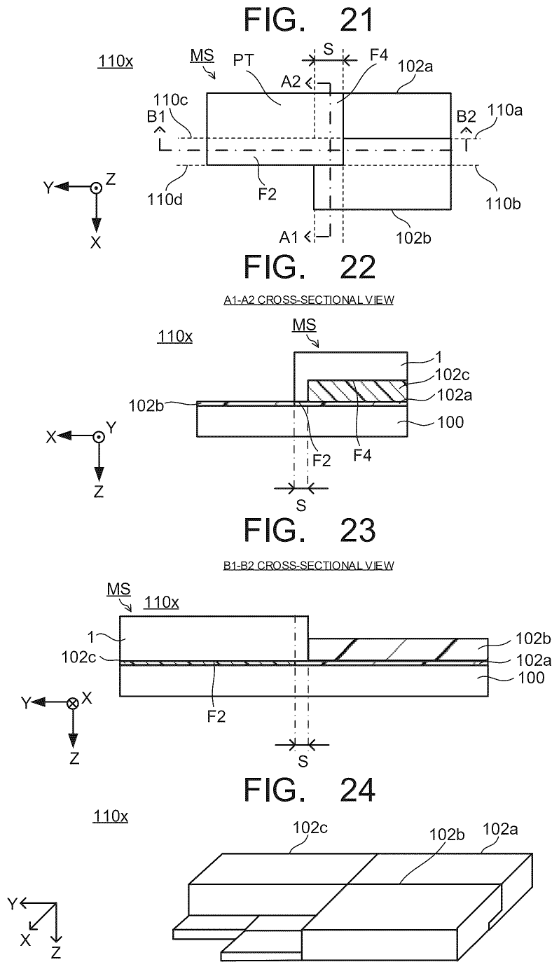

Next, imprinting is performed on the shot area 110c. FIG. 21, FIG. 22, FIG. 23, and FIG. 24 are schematic views for explaining an example of imprinting on the shot area 110c. FIG. 21 schematically illustrates the upper surface of the intersection 110x. FIG. 22 schematically illustrates an X-Z cross-section of the intersection 110x at a line segment A1-A2 in FIG. 21. FIG. 23 schematically illustrates a Y-Z cross-section of the intersection 110x at a line segment B1-B2 in FIG. 21. FIG. 24 schematically illustrates an example of a three-dimensional shape of a part of the cured imprint material layer 102c.

In the example of imprinting on the shot area 110c, the template TP is pressed against the imprint material layer 102c formed in the shot area 110c so that the faces F2 and F4 overlap the space S in the Z-axis direction, the pattern surface PT is brought into contact with the imprint material layer 102c to form the imprint material layer 102c, and the template TP is separated after the imprint material layer 102c is cured.

In FIG. 22, the imprint material layer 102c is in contact with the face F4 and formed according to the height H4. In FIG. 23, the imprint material layer 102c is in contact with the face F2 and formed according to the height H2, and is in contact with the face F4 and formed according to the height H4. Thus, a part of the imprint material layer 102c is stacked to the same height as a part of the imprint material layer 102b adjacent to a part of the imprint material layer 102a in the space S. This allows a cured layer of the imprint material layer 102c to be formed. When the template TP with the surface illustrated in FIG. 6 is used, for example, a cured layer of the imprint material layer 102c with the shape illustrated in FIG. 24 can be formed. A pattern corresponding to the depression D of the template TP, which is not illustrated in the figure, is transferred to a rectangular protrusion of the imprint material layer 102c in FIG. 24.

Note that FIG. 21, FIG. 22, and FIG. 23 are illustrated so that the end portion of the face F2 in the X-axis direction overlaps the end portion of the space S between the shot area 110c and the shot area 110d in the X-axis direction viewed from the Z-axis direction, and the end portion of the face F4 in the Y-axis direction overlaps the end portion of the space S between the shot area 110a and the shot area 110c in the Y-axis direction viewed from the Z-axis direction. However, the face F2 only needs to overlap at least a part of the space S between the shot area 110c and the shot area 110d viewed from the Z-axis direction, and the face F4 only needs to overlap at least a part of the space S between the shot area 110a and the shot area 110c viewed from the Z-axis direction.

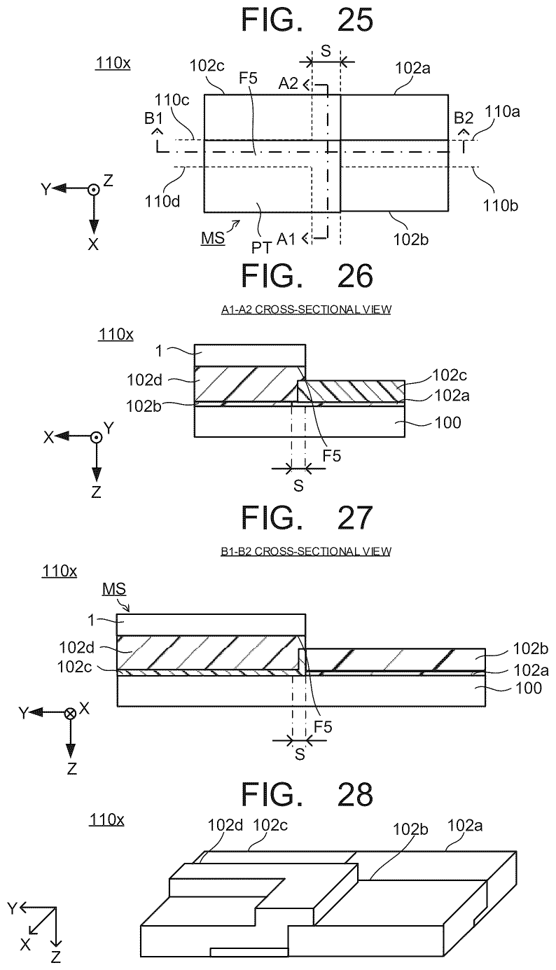

Next, imprinting is performed on the shot area 110d. FIG. 25, FIG. 26, FIG. 27, and FIG. 28 are schematic views for explaining an example of imprinting on the shot area 110d. FIG. 25 schematically illustrates the upper surface of the intersection 110x. FIG. 26 schematically illustrates an X-Z cross-section of the intersection 110x at a line segment A1-A2 in FIG. 25. FIG. 27 schematically illustrates a Y-Z cross-section of the intersection 110x at a line segment B1-B2 in FIG. 25. FIG. 28 schematically illustrates an example of a three-dimensional shape of a part of the cured imprint material layer 102d.

In the example of imprinting on the shot area 110d, the template TP is pressed against the imprint material layer 102d formed in the shot area 110d so that the face F5 overlaps the space S in the Z-axis direction, the pattern surface PT is brought into contact with the imprint material layer 102d to form the imprint material layer 102d, and the template TP is separated after the imprint material layer 102d is cured.

In FIG. 26, the imprint material layer 102d is in contact with the face F5 and formed according to the height H5. In FIG. 27, the imprint material layer 102d is in contact with the face F5 and formed according to the height H5. Thus, a part of the imprint material layer 102d is stacked on each of a part of the imprint material layer 102a, a part of the imprint material layer 102b, and a part of the imprint material layer 102c in the space S. This allows a cured layer of the imprint material layer 102d to be formed. When the template TP with the surface illustrated in FIG. 6 is used a cured layer of the imprint material layer 102d with the shape, for example, illustrated in FIG. 28 can be formed. A pattern corresponding to the depression D of the template TP, which is not illustrated in the figure, is transferred to a rectangular protrusion of the imprint material layer 102d in FIG. 28.

Note that FIG. 25, FIG. 26, and FIG. 27 are illustrated so that the end portion of the face F5 in the X-axis direction overlaps the end portion of the space S between the shot area 110c and the shot area 110d in the X-axis direction viewed from the Z-axis direction, and the end portion of the face F5 in the Y-axis direction overlaps the end portion of the space S between the shot area 110b and the shot area 110d in the Y-axis direction viewed from the Z-axis direction. However, the face F5 only needs to overlap at least a part of the space S between the shot area 110c and the shot area 110d viewed from the Z-axis direction, and the face F5 only needs to overlap at least a part of the space S between the shot area 110b and the shot area 110d viewed from the Z-axis direction. When the imprint material is fluid, a portion of the imprint material layer 102d formed by the face F5 is shifted in the X-axis or Y-axis direction relative to the space S when viewed from the Z-axis direction, and may overlap the imprint material layer 102a, imprint material layer 102b, and imprint material layer 102c, as illustrated in FIG. 28.

When the imprint material layer 102a, imprint material layer 102b, imprint material layer 102c, and imprint material layer 102d have the same height as each other in the portions adjacent to each other, gaps of, for example, 1 μm or more and 2 μm or less may be generated among them.

As described above, the imprint method of this embodiment uses the template TP with the faces F3 and F4 having the higher height than the faces F1 and F2, and with the face F5 having the even higher height than the faces F3 and F4 at the corner C1, and imprints the shot area 110a, the shot area 110b, the shot area 110c, and the shot area 110d in that order. When forming the shot area 110b and the shot area 110c, the template TP is brought into contact so that the face F3 or F4 overlaps the space S viewed from the Z-axis direction, and when forming the imprint material layer 102d, the template TP is brought into contact so that the face F5 overlaps the space S viewed from the Z-axis direction. This allows the imprint material layer 102a, imprint material layer 102b, imprint material layer 102c, and imprint material layer 102d to be partially stacked without tilting the template TP. Thus, generation of gaps among the imprint material layer 102a, imprint material layer 102b, imprint material layer 102c, and imprint material layer 102d at the intersection 110x, especially at its center, can be suppressed. This can reduce, for example, a manufacturing cost of semiconductor devices, since, for example, a separate process to fill the above gaps afterward becomes unnecessary.

When the template TP does not have the face F5, the space S should be wider so that the imprint patterns of the imprint material layer 102a, imprint material layer 102b, imprint material layer 102c, and imprint material layer 102d do not overlap each other at the intersection 110x. However, when the space S is made wider, gaps among the imprint material layer 102a, imprint material layer 102b, imprint material layer 102c, and imprint material layer 102d are likely to be generated. When gaps are generated, as mentioned above, for example, the portion overlapping the space S is etched more than necessary when the imprint material layer is used as an etching mask to etch the object 100, and there is a problem that conductive layers such as wiring in the object 100 are exposed unnecessarily.

### (First Further Example of Imprint Method)

A first further example of the imprint method is explained below. In the first further example, the respective heights of the faces F1, F2, F3, F4, and F5 are different from the above example of the imprint method. In the following, different points from the above example of the imprint method will be explained, and for the other portions, the explanation in the above example of the imprint method can be used as appropriate.

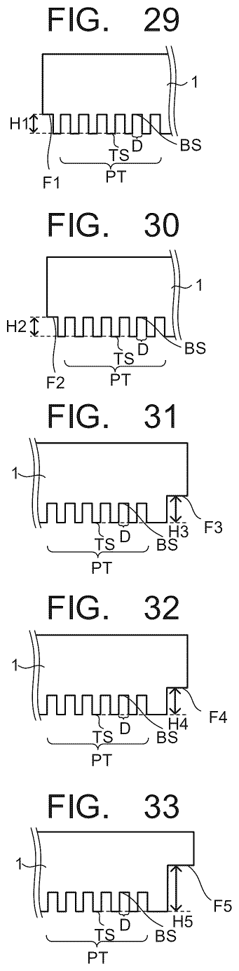

FIG. 29 to FIG. 33 are enlarged views each illustrating a part of the pattern of the mesa MS illustrated in FIG. 2, where the Z direction is opposite to FIG. 2. FIG. 29 is a cross-sectional schematic view of a part of the mesa MS in the Z-axis direction in the first further example. FIG. 29 illustrates the face F1. The face F1 has the height H1 relative to the face TS of the pattern surface PT. The height H1 is greater than the height of the face TS. A height of the face F1 may be as same as a height of the face TS or smaller than the height of the lowermost face BS of the pattern surface PT relative to the face TS.

FIG. 30 is a cross-sectional schematic view of a part of the mesa MS in the Z-axis direction in the first further example. FIG. 30 illustrates the face F2. The face F2 has the height H2 relative to the face TS. The height H2 is greater than the height of the face TS. A height of the face F2 may be as same as the height of the face TS or smaller than the height of the lowermost face BS of the pattern surface PT relative to the face TS. The height H2 is, for example, the same height as the height H1.

FIG. 31 is a cross-sectional schematic view of a part of the mesa MS in the Z-axis direction in the first further example. FIG. 31 illustrates the face F3. The face F3 has the height H3 relative to the face TS. The height H3 is greater than the height of the face TS, and greater than each of the height H1 and the height H2. The height H3 is greater than the height of the lowermost face BS relative to the face TS.

FIG. 32 is a cross-sectional schematic view of a part of the mesa MS in the Z-axis direction in the first further example. FIG. 32 illustrates the face F4. The face F4 has the height H4 relative to the face TS. The height H4 is greater than the height of the face TS and greater than each of the height H1 and the height H2. The height H4 is greater than the height of the lowermost face BS relative to the face TS. The height H4 is, for example, the same height as the height H3.

FIG. 33 is a cross-sectional schematic view of a part of the mesa MS in the Z-axis direction in the first further example. FIG. 33 illustrates the face F5. The face F5 has the height H5 relative to the face TS. The height H5 is greater than the height of the face TS and greater than each of the height H3 and the height H4. The height H5 is greater than the height of the lowermost face BS relative to the face TS.

The heights of the faces F1, F2, F3, F4, and F5 can be adjusted by etching, for example, the substrate 1 in the thickness direction by dry etching using, for example, an etching mask. By making the height H1 and height H2 the same as the height of the lowermost face BS, the increase in the number of etching masks required for etching can be reduced.

In the first further example of the above imprint method, imprinting is performed in the same order as in the above imprint method: the shot area 110a, shot area 110b, shot area 110c, and shot area 110d illustrated in FIG. 12.

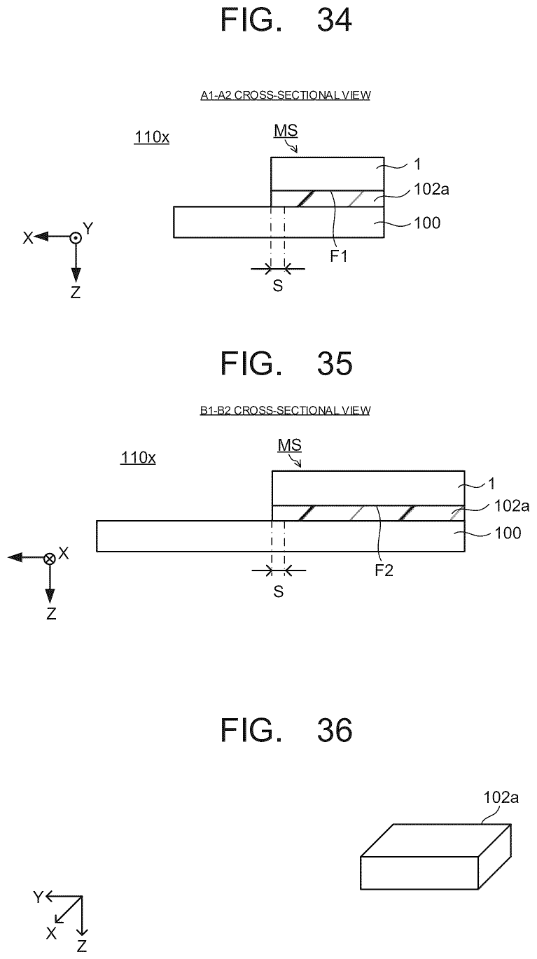

First, imprinting is performed on the shot area 110a, as illustrated in FIG. 13. FIG. 34, FIG. 35, and FIG. 36 are schematic views for explaining an example of imprinting on the shot area 110a. FIG. 34 schematically illustrates the X-Z cross-section of the intersection 110x at the line segment A1-A2 in FIG. 13. FIG. 35 schematically illustrates the Y-Z cross-section of the intersection 110x at the line segment B1-B2 in FIG. 13. FIG. 36 schematically illustrates an example of a three-dimensional shape of a part of the cured imprint material layer 102a.

In the example of imprinting on the shot area 110a, the template TP is pressed against the imprint material layer 102a formed in the shot area 110a so that the faces F1 and F2 overlap the space S in the Z-axis direction, the pattern surface PT is brought into contact with the imprint material layer 102a to form the imprint material layer 102a, and the template TP is separated after the imprint material layer 102a is cured.

In FIG. 34, the imprint material layer 102a is in contact with the face F1 and formed according to the height H1. In FIG. 35, the imprint material layer 102a is in contact with the face F2 and formed according to the height H2. At this time, a thickness of a part of the imprint material layer 102a in the space S is greater than the thickness of a part of the imprint material layer 102a in the space S illustrated in FIG. 15. This allows a cured layer of the imprint material layer 102a with the shape illustrated in FIG. 36, for example, to be formed.

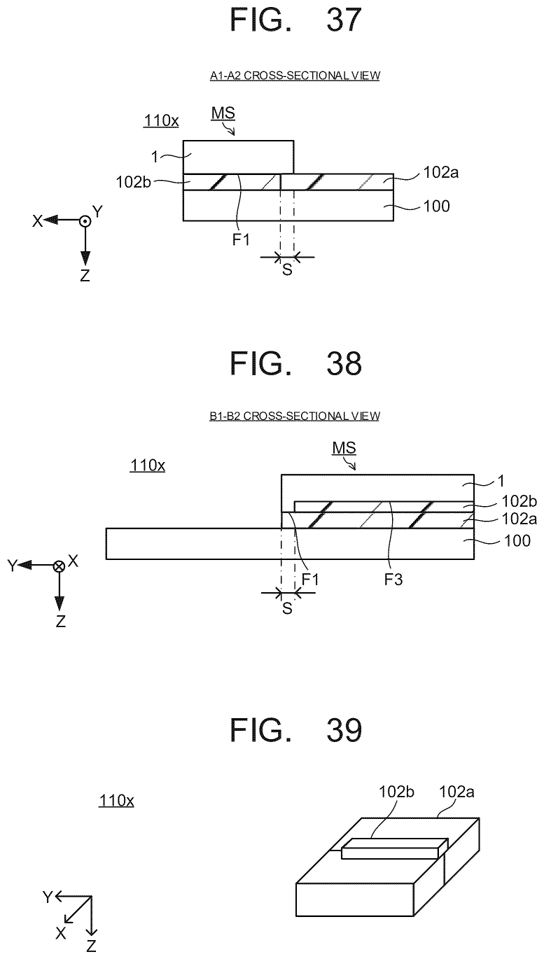

Next, imprinting is performed on the shot area 110b as illustrated in FIG. 17. FIG. 37, FIG. 38, and FIG. 39 are schematic views for explaining an example of imprinting on the shot area 110b of the first further example. FIG. 37 schematically illustrates the X-Z cross-section of the intersection 110x at the line segment A1-A2 in FIG. 17. FIG. 38 schematically illustrates the Y-Z cross-section of the intersection 110x at the line segment B1-B2 in FIG. 17. FIG. 39 schematically illustrates an example of a three-dimensional shape of a part of the cured imprint material layer 102b.

In the example of imprinting on the shot area 110b, the template TP is pressed against the imprint material layer 102b formed in the shot area 110b so that the faces F1 and F3 overlap the space S in the Z-axis direction, the pattern surface PT is brought into contact with the imprint material layer 102b to form the imprint material layer 102b, and the template TP is separated after the imprint material layer 102b is cured.

In FIG. 37, the imprint material layer 102b is in contact with the face F1 and formed according to the height H1, but a part of the cured imprint material layer 102a is also in contact with the face F1, so a portion of the imprint material layer 102b having the same height as the imprint material layer 102a is not stacked on a part of the imprint material layer 102a. In FIG. 38, a part of the imprint material layer 102b is in contact with the face F1 and formed according to the height H1, so the portion of the imprint material layer 102b having the same height as the imprint material layer 102a is not stacked on a part of the imprint material layer 102a. Another part of the imprint material layer 102b is in contact with the face F3, and formed according to the height H3, so a part of the imprint material layer 102b is stacked on a part of the imprint material layer 102a in the space S. At this time, a thickness of a stack of the part of the imprint material layer 102a and the part of the imprint material layer 102b in the space S is greater than the thickness of the stack of the part of the imprint material layer 102a and the part of the imprint material layer 102b in the space S illustrated in FIG. 19. This allows a cured layer of the imprint material layer 102b with the shape illustrated in FIG. 39 to be formed.

When the imprint material is fluid, a portion of the imprint material layer 102b formed by the face F3 is shifted in the X-axis direction relative to the space S when viewed from the Z-axis direction and may overlap the imprint material layer 102a, as illustrated in FIG. 39.

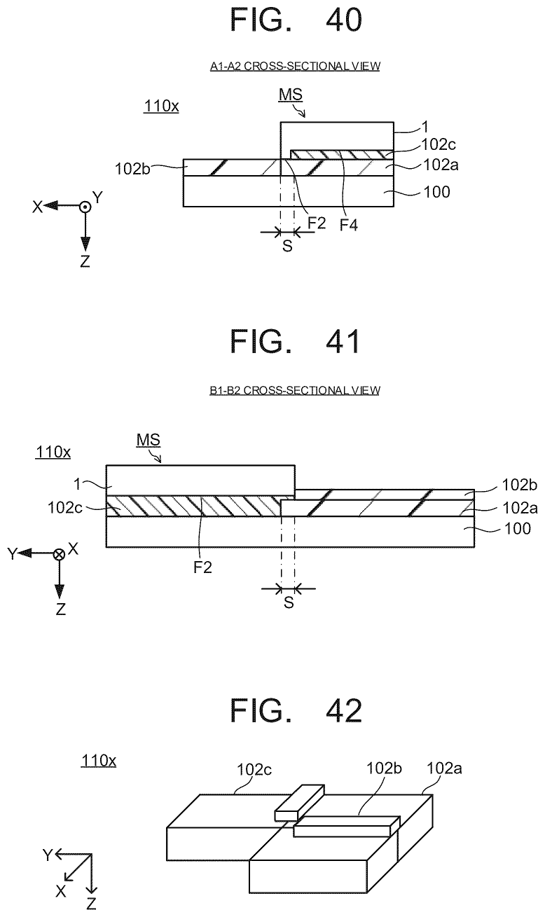

Next, imprinting is performed on the shot area 110c as illustrated in FIG. 21. FIG. 40, FIG. 41, and FIG. 42 are schematic views for explaining an example of imprinting on the shot area 110c in the first further example. FIG. 40 schematically illustrates the X-Z cross-section of the intersection 110x at the line segment A1-A2 in FIG. 21. FIG. 41 schematically illustrates the Y-Z cross-section of the intersection 110x at the line segment B1-B2 in FIG. 21. FIG. 42 schematically illustrates an example of a three-dimensional shape of a part of the cured imprint material layer 102c.

In the example of imprinting on the shot area 110c, the template TP is pressed against the imprint material layer 102c formed in the shot area 110c so that the faces F2 and F4 overlap the space S in the Z-axis direction, the pattern surface PT is brought into contact with the imprint material layer 102c to form the imprint material layer 102c, and the template TP is separated after the imprint material layer 102c is cured.

In FIG. 40, the imprint material layer 102c is in contact with the face F4 and formed according to the height H4. In FIG. 41, the imprint material layer 102c is in contact with the face F2 and formed according to the height H2, and is in contact with the face F4 and formed according to the height H4. Thus, a part of the imprint material layer 102c is stacked to the same height as a part of the imprint material layer 102b adjacent to a part of the imprint material layer 102a in the space S. At this time, a thickness of a stack of the part of the imprint material layer 102a and the part of the imprint material layer 102c in the space S is greater than the thickness of the stack of the part of the imprint material layer 102a and the part of the imprint material layer 102c in the space S illustrated in FIG. 23. This allows a cured layer of the imprint material layer 102c with the shape illustrated in FIG. 42 to be formed.

When the imprint material is fluid, a portion of the imprint material layer 102c formed by the face F4 is shifted in the Y-axis direction relative to the space S when viewed from the Z-axis direction and may overlap the imprint material layer 102a, as illustrated in FIG. 42.

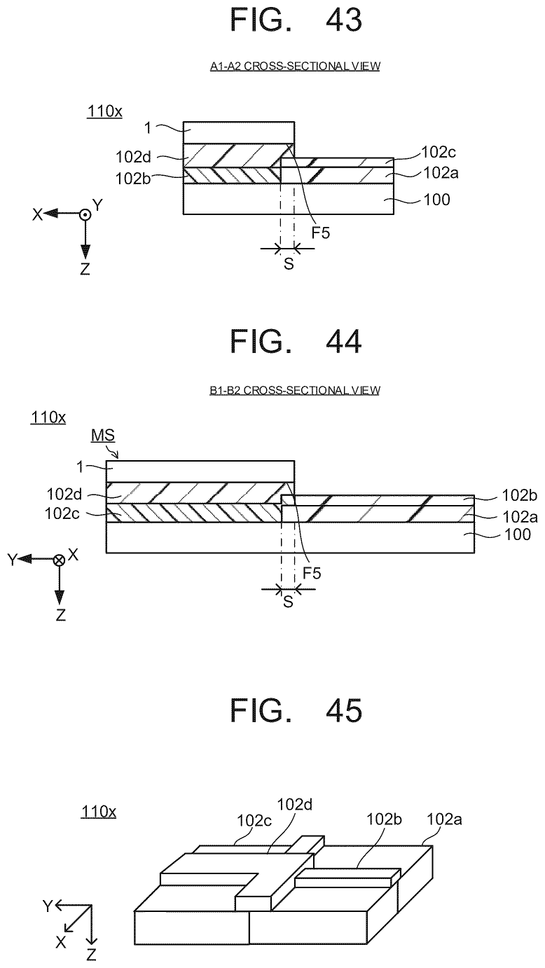

Next, imprinting is performed on the shot area 110d as illustrated in FIG. 25. FIG. 43, FIG. 44, and FIG. 45 are schematic views for explaining an example of imprinting on the shot area 110d in the first further example. FIG. 43 schematically illustrates the X-Z cross-section of the intersection 110x at the line segment A1-A2 in FIG. 25. FIG. 44 schematically illustrates the Y-Z cross-section of the intersection 110x at the line segment B1-B2 in FIG. 25. FIG. 45 schematically illustrates an example of a three-dimensional shape of a part of the cured imprint material layer 102d.

In the example of imprinting on the shot area 110d, the template TP is pressed against the imprint material layer 102d formed in the shot area 110d so that the face F5 overlaps the space S in the Z-axis direction, the pattern surface PT is brought into contact with the imprint material layer 102d to form the imprint material layer 102d, and the template TP is separated after the imprint material layer 102d is cured.

In FIG. 43, the imprint material layer 102d is in contact with the face F5 and formed according to the height H5. In FIG. 44, the imprint material layer 102d is in contact with the face F5 and formed according to the height H5. Thus, a part of the imprint material layer 102d is stacked on each of a part of the imprint material layer 102a, a part of the imprint material layer 102b, and a part of the imprint material layer 102c in the space S. At this time, a thickness of a stack of the part of the imprint material layer 102a, the part of the imprint material layer 102c, and the part of the imprint material layer 102d in the space S is greater than the thickness of the stack of the part of the imprint material layer 102a, the part of the imprint material layer 102c, and the part of the imprint material layer 102d in the space S illustrated in FIG. 27. This allows a cured layer of the imprint material layer 102d with the shape illustrated in FIG. 45 to be formed.

When the imprint material is fluid, a portion of the imprint material layer 102d formed by the face F5 is shifted in the X-axis or Y-axis direction relative to the space S when viewed from the Z-axis direction and may overlap the imprint material layer 102a, the imprint material layer 102b, and the imprint material layer 102c as illustrated in FIG. 45.

As described above, the first further example of the imprint method uses the template TP with the faces F1 and F2 having the higher height than the uppermost face of the pattern surface PT, with the faces F3 and F4 having the higher height than the faces F1 and F2, and with the face F5 having the even higher height than the faces F3 and F4 at the corner C1, and imprints the shot area 110a, shot area 110b, shot area 110c, and shot area 110d in that order. When forming the shot area 110b and the shot area 110c, the template TP is brought into contact so that the face F3 or F4 overlaps the space S in the Z-axis direction, and when forming the imprint material layer 102d, the template TP is brought into contact so that the face F5 overlaps the space S in the Z-axis direction. This allows the imprint material layer 102a, imprint material layer 102b, imprint material layer 102c, and imprint material layer 102d to be partially stacked without tilting the template TP. Thus, generation of gaps among the imprint material layer 102a, imprint material layer 102b, imprint material layer 102c, and imprint material layer 102d at the intersection 110x can be suppressed. This can reduce, for example, a manufacturing cost of semiconductor devices, since, for example, a separate process to fill the above gaps afterward becomes unnecessary.

### (Second Further Example of Imprint Method)

Next, a second further example of the imprint method is explained below. In the second further example, the location of the face F5 is different from the above example of the imprint method. In the following, different points from the above example of the imprint method will be explained, and for the other portions, the explanation in the above example of the imprint method can be used as appropriate.

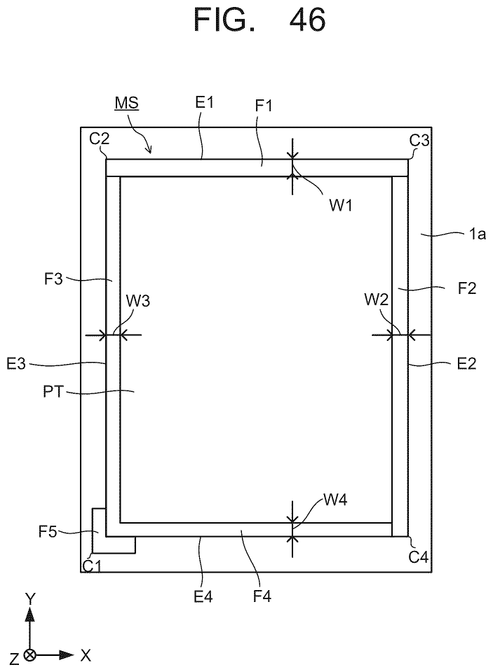

FIG. 46 is a plan schematic view for explaining a structure example of the surface of the mesa MS in the second further example. FIG. 46 illustrates X-, Y-, and Z-axis directions of the mesa MS.

The surface of the mesa MS has the pattern surface PT, face F1, and face F2 as same as the surface of the mesa MS illustrated in FIG. 5, and the locations of the faces F3, F4, and F5 are different from those in FIG. 5. Each height from the face TS is the same as in FIG. 5.

The face F3 is provided along the end E3. The face F3 extends along the end E3 from the corner C1 to one end of the face F1 between the corners C1 and C2.

The face F4 is provided along the end E4. The face F4 extends along the end E4 from the corner C1 to one end of the face F2 between the corners C1 and C4.

The face F5 is provided along the corner C1. The face F5 is provided outside each of the faces F3 and F4. The face F5 extends along the end E3 from the corner C1 toward the corner C2 and extends along the end E4 from the corner C1 toward the corner C4.

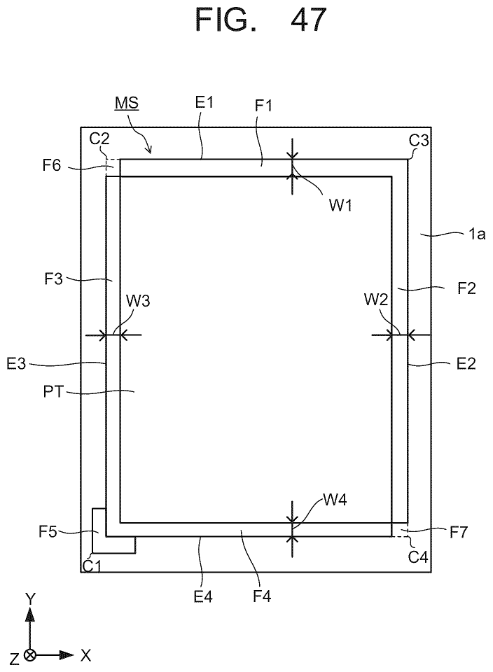

The structure of the surface of the mesa MS is not limited to the structure illustrated in FIG. 46. FIG. 47 is a plan schematic view for explaining another structure example of the surface of mesa MS in the second further example. FIG. 47 differs from FIG. 46 in that it has the face F6 near the corner C2 and the face F7 near the corner C4. In the following, different points from FIG. 46 will be explained, and for the other portions, the explanation of FIG. 46 can be used as appropriate.

The face F1 extends along the end E1 from one end of the face F6 to the corner C3 between the corners C2 and C3.

The face F2 extends along the end E2 from the corner C3 to one end of the face F7 between the corners C3 and C4.

The face F3 extends along the end E3 from the corner C1 to the other end of the face F6 between the corners C1 and C2.

The face F4 extends along the end E4 from the corner C1 to the other end of the face F7 between the corners C1 and C4.

The face F6 is provided along the corner C2. The face F6 extends along the end E1 from the corner C2 to one end of the face F1, and extends along the end E3 from the corner C2 to the other end of the face F3. As other explanations of the face F6, the explanation of the face F6 in FIG. 6 can be used as appropriate.

The face F7 is provided along the corner C4. The face F7 extends along the end E2 from the corner C4 to one end of the face F2 and extends along the end E4 from the corner C4 to the other end of the face F4. As other explanations of the face F7, the explanation of the face F7 in FIG. 6 can be used as appropriate.

In the second further example of the above imprint method, imprinting is performed in the same order as the above imprint method: the shot area 110a, shot area 110b, shot area 110c, and shot area 110d illustrated in FIG. 12. Since imprinting on each of the shot area 110a, shot area 110b, and shot area 110c is the same as the above imprint method, the explanation is omitted here.

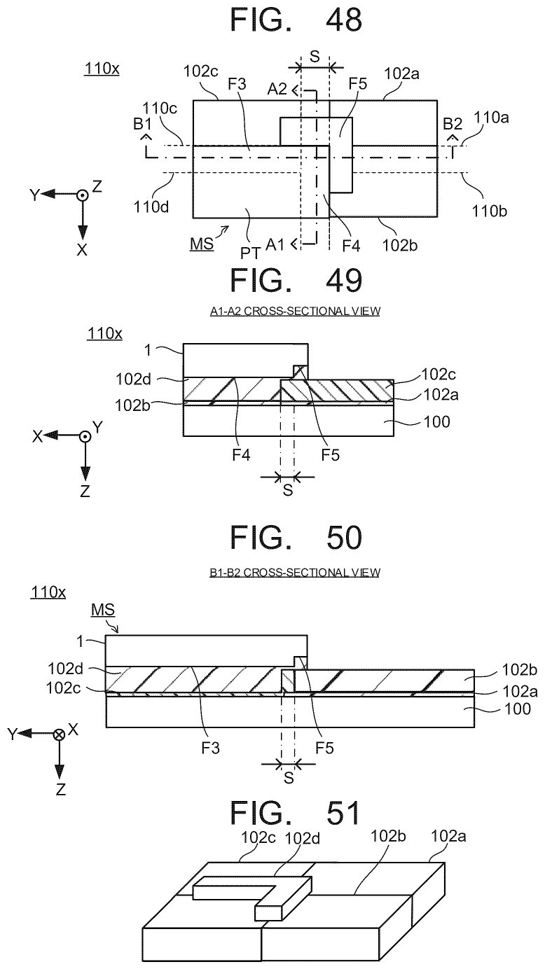

FIG. 48, FIG. 49, FIG. 50, and FIG. 51 are schematic views for explaining an example of imprinting on the shot area 110d. FIG. 48 schematically illustrates the upper surface of the intersection 110x. FIG. 49 schematically illustrates an X-Z cross-section of the intersection 110x at a line segment A1-A2 in FIG. 48. FIG. 50 schematically illustrates a Y-Z cross-section of the intersection 110x at a line segment B1-B2 in FIG. 48. FIG. 51 schematically illustrates an example of a three-dimensional shape of a part of the cured imprint material layer 102d.

In the example of imprinting on the shot area 110d, the template TP is pressed against the imprint material layer 102d formed in the shot area 110d so that the face F5 overlaps the space S in the Z-axis direction, the pattern surface PT is brought into contact with the imprint material layer 102d to form the imprint material layer 102d, and the template TP is separated after the imprint material layer 102d is cured.

In FIG. 49, the imprint material layer 102d is in contact with the face F4 and formed according to the height H4, and is in contact with the face F5 and formed according to the height H5. In FIG. 50, the imprint material layer 102d is in contact with the face F3 and formed according to the height H3, and is in contact with the face F5 and formed according to the height H5. Thus, a part of the imprint material layer 102d is stacked on each of a part of the imprint material layer 102a, a part of the imprint material layer 102b, and a part of the imprint material layer 102c in the space S. Further, a part of the imprint material layer 102d is stacked on each of a part of the imprint material layer 102a, a part of the imprint material layer 102b, and a part of the imprint material layer 102c so as to overlap the shot area 110a, the shot area 110b, and the shot area 110c in the Z-axis direction. This allows the cured layer of the imprint material layer 102a, the cured layer of the imprint material layer 102b, the cured layer of the imprint material layer 102c, and the cured layer of the imprint material layer 102d to be formed. When the template TP with the surface illustrated in FIG. 47 is used, for example, the cured layer of imprint material layer 102a, the cured layer of imprint material layer 102b, the cured layer of imprint material layer 102c, and the cured layer of imprint material layer 102d can be formed with the shape illustrated in FIG. 51.

When the imprint material is fluid, a portion of the imprint material layer 102d formed by the face F5 is shifted in the X-axis or Y-axis direction relative to the space S when viewed from the Z-axis direction, and may overlap the imprint material layer 102a, the imprint material layer 102b, and the imprint material layer 102c as illustrated in FIG. 51.

As described above, the second further example of the imprint method uses the template TP with the faces F3 and F4 each having the higher height than the faces F1 and F2, and with the face F5 having the even higher height than the faces F3 and F4 and provided outside the face F4 at the corner C1, and imprints the shot area 110a, shot area 110b, shot area 110c, and shot area 110d in that order. When forming the shot area 110b and the shot area 110c, the template TP is brought into contact so that the face F3 or F4 overlaps the space S in the Z-axis direction, and when forming the imprint material layer 102d, the template TP is brought into contact so that the face F5 overlaps the space S in the Z-axis direction. This allows the imprint material layer 102a, imprint material layer 102b, imprint material layer 102c, and imprint material layer 102d to be partially stacked without tilting the template TP. Thus, generation of gaps among the imprint material layer 102a, imprint material layer 102b, imprint material layer 102c, and imprint material layer 102d at the intersection 110x can be suppressed. This can reduce, for example, a manufacturing cost of semiconductor devices, since, for example, a separate process to fill the above gaps afterward becomes unnecessary.

### (Third Further Example of Imprint Method)

Next, a third further example of the imprint method is explained below. The third further example differs from the above imprint method example in that a peripheral edge of the mesa MS has a jigsaw shape. The jigsaw shape is a shape in which each edge forming the peripheral edge of the mesa MS is refracted and adjacent edges interlock with each other when the surfaces of a plurality of mesas MS are arranged adjacent to each other. In the following, different points from the above example of the imprint method will be explained, and for the other portions, the explanation in the above example of the imprint method can be used as appropriate.

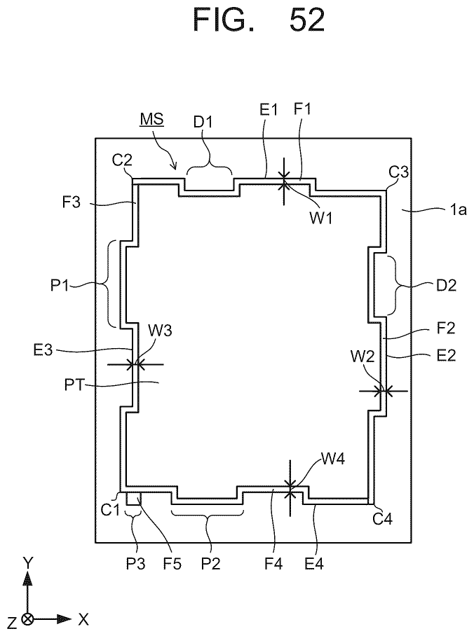

FIG. 52 is a plan schematic view for explaining a structure example of the surface of the mesa MS. FIG. 52 illustrates the X-, Y-, and Z-axis directions of the mesa MS.

The surface of the mesa MS has the pattern surface PT, face F1, face F2, face F3, face F4, and face F5. The faces F1, F2, F3, F4, and F5 are provided around the pattern surface PT. The pattern surface PT may be surrounded by the faces F1, F2, F3, F4, and F5. Each height from the face TS is the same as in FIG. 5.

The face F1 is provided along the end E1. The end E1 is refracted in a dent and protruding state along the X-axis direction and has a depressed portion D1 that depresses inside the surface of the mesa MS, for example. The face F1 extends along the end E1 from the corner C2 to the corner C3 between the corners C2 and C3, while refracting to form depressions and protrusions.

The face F2 is provided along the end E2. The end E2 is refracted in a dent and protruding state along the Y-axis direction and has a depressed portion D2 that depresses inside the surface of the mesa MS, for example. The face F2 extends along the end E2 from the corner C3 to one end of the face F4 between the corners C3 and C4, while refracting to form depressions and protrusions. The face F2 forms one continuous plane together with the face F1.

The face F3 is provided along the end E3. The end E3 is refracted in a dent and protruding state along the X-axis direction and has a protruding portion P1 that protrudes outside the surface of the mesa MS, for example. The protruding portion P1 is provided at an opposite side of the depressed portion D2 and can fit or engage with the depressed portion D2 when placed adjacent to the depressed portion D2. The face F3 extends along the end E3 from the corner C1 to the corner C2 between the corners C1 and C2.

The face F4 is provided along the end E4. The end E4 is refracted in a dent and protruding state along the X-axis direction and has a protruding portion P2 and a protruding portion P3 that protrude outside the surface of the mesa MS, for example. The protruding portion P2 is provided at an opposite side of the depressed portion D1 and can fit or engage with the depressed portion D1 when placed adjacent to the depressed portion D1. The protruding portion P3 is provided adjacent to the corner C1. The face F4 extends along the end E4 from the corner C1 to the corner C4 between the corners C1 and C4.

The face F5 is provided at the protruding portion P3. The face F5 is provided outside the face F4, for example, but not limited thereto, the face F5 may protrude from the peripheral edge of the pattern surface PT without forming an area between the pattern surface PT of the face F4 and the face F5. A planar shape of the face F5 is not limited, but is, for example, rectangular.

In the third further example of the above imprint method, imprinting is performed in the same order as in the above imprint method: the shot area 110a, the shot area 110b, the shot area 110c, and the shot area 110d.

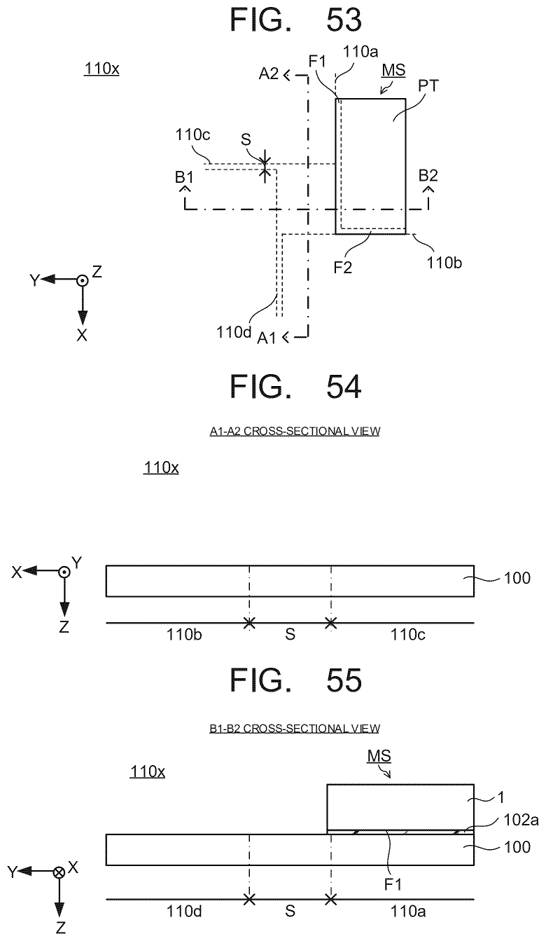

First, imprinting is performed on the shot area 110a. FIG. 53, FIG. 54, and FIG. 55 are schematic views for explaining an example of imprinting on the shot area 110a in the third further example. FIG. 53 schematically illustrates the upper surface of the intersection 110x among the shot area 110a, the shot area 110b, the shot area 110c, and the shot area 110d. FIG. 54 schematically illustrates an X-Z cross-section of the intersection 110x at a line segment A1-A2 in FIG. 53. FIG. 55 schematically illustrates a Y-Z cross-section of the intersection 110x at a line segment B1-B2 in FIG. 53.

In the example of imprinting on the shot area 110a, the template TP is pressed against the imprint material layer 102a formed in the shot area 110a so that the faces F1 and F2 overlap the space S in the Z-axis direction, the pattern surface PT is brought into contact with the imprint material layer 102a to form the imprint material layer 102a, and the template TP is separated after the imprint material layer 102a is cured.

In FIG. 54, the surface 100a of the object 100 remains exposed because the imprint material layer 102 is not formed. In FIG. 55, the imprint material layer 102a is in contact with the face F1 and formed according to the height H1.

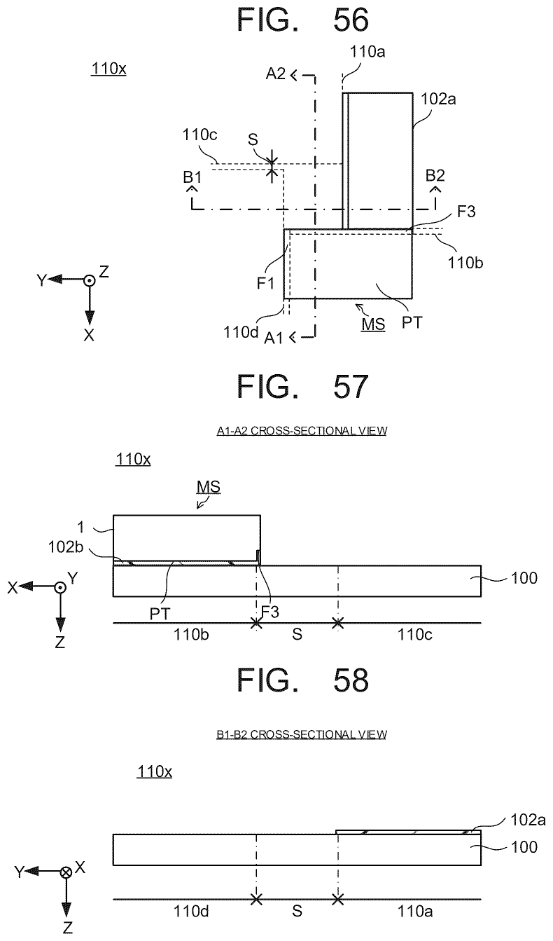

Next, imprinting is performed on the shot area 110b. FIG. 56, FIG. 57, and FIG. 58 are schematic views for explaining an example of imprinting on the shot area 110b in the third further example. FIG. 56 schematically illustrates the upper surface of the intersection 110x. FIG. 57 schematically illustrates an X-Z cross-section of the intersection 110x at a line segment A1-A2 in FIG. 56. FIG. 58 schematically illustrates a Y-Z cross-section of the intersection 110x at a line segment B1-B2 in FIG. 56.

In the example of imprinting on the shot area 110b, the template TP is pressed against the imprint material layer 102b formed in the shot area 110b so that the faces F1 and F3 overlap the space S in the Z-axis direction, the pattern surface PT is brought into contact with the imprint material layer 102b to form the imprint material layer 102b, and the template TP is separated after the imprint material layer 102b is cured.

In FIG. 57, the imprint material layer 102b is in contact with the pattern surface PT and formed according to the imprint pattern, with the face F1 and formed according to the height H1, and with the face F3 and formed according to the height H3. In FIG. 58, the surface of the mesa MS remains exposed without being in contact at the surface of the cured imprint material layer 102a.

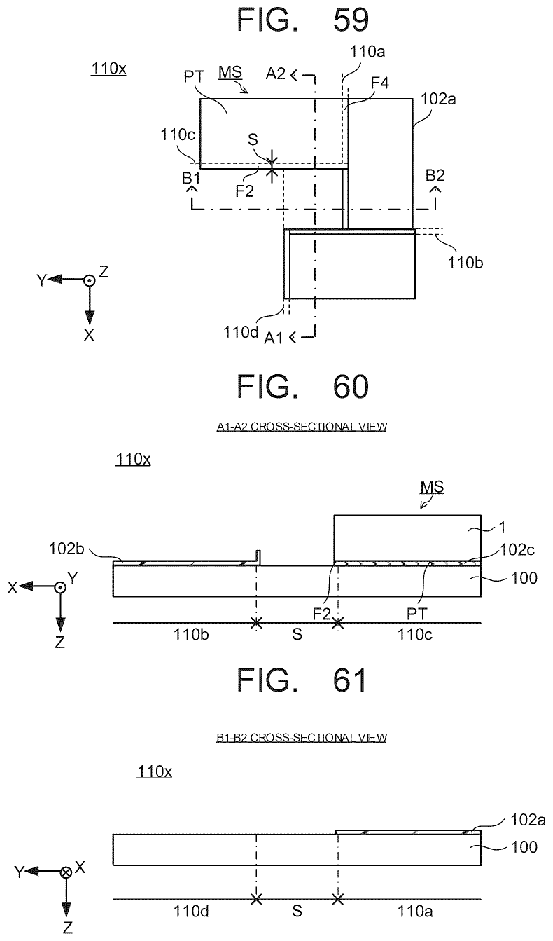

Next, imprinting is performed on the shot area 110c. FIG. 59, FIG. 60, and FIG. 61 are schematic views for explaining an example of imprinting on the shot area 110c in the third further example. FIG. 59 schematically illustrates the upper surface of the intersection 110x. FIG. 60 schematically illustrates an X-Z cross-section of the intersection 110x at a line segment A1-A2 in FIG. 59. FIG. 61 schematically illustrates a Y-Z cross-section of the intersection 110x at a line segment B1-B2 in FIG. 59.

In the example of imprinting on the shot area 110c, the template TP is pressed against the imprint material layer 102c formed in the shot area 110c so that the faces F2 and F4 overlap the space S in the Z-axis direction, the pattern surface PT is brought into contact with the imprint material layer 102c to form the imprint material layer 102c, and the template TP is separated after the imprint material layer 102c is cured.

In FIG. 60, the imprint material layer 102c is in contact with the pattern surface PT and formed according to the imprint pattern, and with the face F2 and formed according to the height H2. In FIG. 61, the surface of the mesa MS remains exposed without being in contact at the surface of the cured imprint material layer 102c.

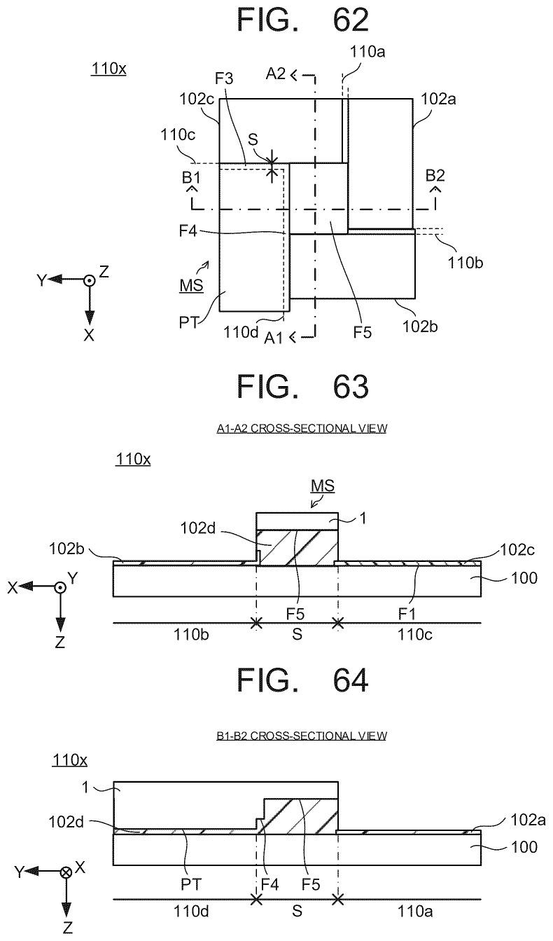

Next, imprinting is performed on the shot area 110d. FIG. 62, FIG. 63, and FIG. 64 are schematic views for explaining an example of imprinting on the shot area 110d in the third further example. FIG. 62 schematically illustrates the upper surface of the intersection 110x. FIG. 63 schematically illustrates an X-Z cross-section of the intersection 110x at a line segment A1-A2 in FIG. 62. FIG. 64 schematically illustrates a Y-Z cross-section of the intersection 110x at a line segment B1-B2 in FIG. 62.

In the example of imprinting on the shot area 110d, the template TP is pressed against the imprint material layer 102d formed in the shot area 110d so that the face F5 overlaps the space S in the Z-axis direction, the pattern surface PT is brought into contact with the imprint material layer 102d to form the imprint material layer 102d, and the template TP is separated after the imprint material layer 102d is cured.

In FIG. 63, the imprint material layer 102d is in contact with the face F5 and formed according to the height H5. In FIG. 64, the imprint material layer 102d is in contact with the face F4 and formed according to the height H4, and with the face F5 and formed according to the height H5. Thus, a part of the imprint material layer 102d extends in the space S.

As described above, the third further example of the imprint method uses the template TP having the jigsaw structure with the faces F3 and F4 having the higher height than the faces F1 and F2, and the face F5 having the even higher height than the faces F3 and F4 and being provided outside the face F4 at the corner C1 to perform the imprinting on the shot area 110a, shot area 110b, shot area 110c, and shot area 110d in that order. When forming the shot area 110b and the shot area 110c, the template TP is brought into contact so that the face F3 or F4 overlaps the space S in the Z-axis direction, and when forming the imprint material layer 102d, the template TP is brought into contact so that the face F5 overlaps the space S in the Z-axis direction. This allows the imprint material layer 102a, imprint material layer 102b, imprint material layer 102c, and imprint material layer 102d to be partially stacked without tilting the template TP. Thus, the generation of gaps among the imprint material layer 102a, imprint material layer 102b, imprint material layer 102c, and imprint material layer 102d at the intersection 110x can be suppressed. This can reduce, for example, a manufacturing cost of semiconductor devices, since, for example, a separate process to fill the above gaps afterward becomes unnecessary.

Note that the first further example, the second further example, and the third further example can be appropriately combined.

(Method of manufacturing Semiconductor Device)

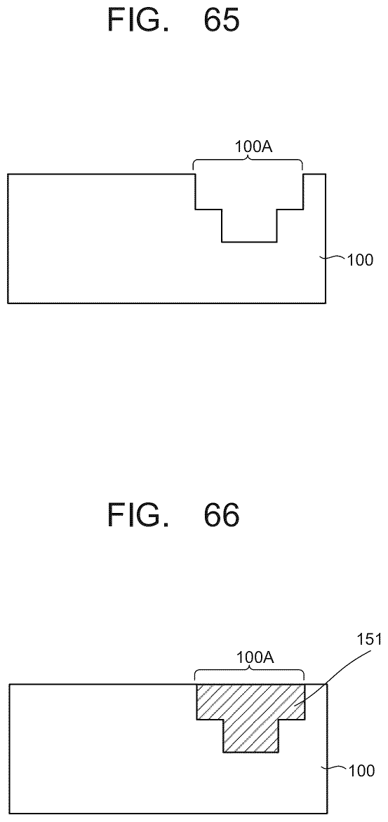

FIG. 65 and FIG. 66 are cross-sectional schematic views for explaining an example of a method of manufacturing a semiconductor device. By processing a part of the object 100 using the cured layer of the imprint material layer 102 formed using the above imprint method, for example, a recess 100A is formed as illustrated in FIG. 65. The object 100 is processed by partially removing a stack forming the object 100 by dry etching, for example. A shape of the object 100 after processing is determined by the shape of the imprint pattern.

Next, a film is deposited on the object 100 after processing, and a layer 151 is formed at the recess 100A by processing the film, as illustrated in FIG. 66. The layer 151 is, for example, a conductive layer containing metallic material. The layer 151 has a function as an embedded wiring, for example.

As described above, this example of the method of this embodiment can manufacture a semiconductor device by processing the object 100 with a cured layer of a coating layer formed using the above imprint method.

While certain embodiments of the present invention have been described above, these embodiments have been presented by way of example only, and are not intended to limit the scope of the invention. Indeed, the novel embodiments described herein may be embodied in a variety of other forms; furthermore, various omissions, substitutions, and changes in the form of the embodiments described herein may be made without departing from the spirit of the inventions. The accompanying claims and their equivalents are intended to cover such forms or furthers as would fall within the scope and spirit of the inventions.

What is claimed is:

1. A template comprising a mesa,
the mesa including:
a pattern surface having an imprint pattern;
a first face provided along a first end of the mesa in a first direction, the first face having a first height relative to an uppermost face of the pattern surface;
a second face provided along a second end of the mesa in a second direction perpendicular to the first direction, the second face having a second height relative to the uppermost face;
a third face provided along a third end of the mesa in the second direction, the third end being opposite the second end, the third face having a third height greater than each of the first height and the second height relative to the uppermost face;
a fourth face provided along a fourth end of the mesa in the first direction, the fourth end being opposite the first end, and the fourth face having a fourth height greater than each of the first height and the second height relative to the uppermost face; and
a fifth face provided along a first corner of the mesa, the first corner being adjacent to each of the third end and the fourth end, and the fifth face having a fifth height greater than each of the third height and the fourth height relative to the uppermost face.

2. The template according to claim 1, wherein
a height of the first face and a height of the second face are the same as a height of the uppermost face, and
a height of the third face and a height of the fourth face are the same as a height of a lowermost face of the pattern surface.

3. The template according to claim 1, wherein
the first height and the second height is smaller than a height of a lowermost face of the pattern surface relative to the uppermost face, and
the third height and the fourth height is greater than the height of the lowermost face of the pattern surface relative to the uppermost face.

4. The template according to claim 1, wherein
the fifth face is provided outside the fourth face.

5. The template according to claim 4, wherein
the first end has a first depressed portion that depresses toward inside the mesa along the second direction,
the second end has a second depressed portion that depresses toward inside the mesa along the first direction,
the third end has a first protruding portion that is provided opposite the first depressed portion and protrudes toward outside the mesa along the second direction,
the fourth end has a second protruding portion that is provided opposite the second depressed portion and protrudes toward outside the mesa along the first direction and a third protruding portion that protrudes toward outside the mesa along the first direction, and
the fifth face is provided at the third protruding portion.

6. An imprint method comprising:
performing imprinting on a surface of an object using a template, wherein the template includes a mesa, and
the mesa has:
a pattern surface including an imprint pattern;
a first face provided along a first end of the mesa in a first direction, the first face having a first height relative to an uppermost face of the pattern surface;
a second face provided along a second end of the mesa in a second direction perpendicular to the first direction, the second face having a second height relative to the uppermost face of the pattern surface;
a third face provided along a third end of the mesa in the second direction, the third end being opposite the second end, and the third face having a third height greater than each of the first height and the second height relative to the uppermost face;
a fourth face provided along a fourth end of the mesa in the first direction, the fourth end being opposite the first end, and the fourth face having a fourth height greater than each of the first height and the second height relative to the uppermost face; and
a fifth face provided along a first corner of the mesa, the first corner being adjacent to each of the third end and the fourth end, and the fifth face having a fifth height greater than each of the third height and the fourth height relative to the uppermost face.

7. The imprint method according to claim 6, wherein
the surface includes:
a first shot area;
a second shot area adjacent to the first shot area in a first direction of the surface;
a third shot area adjacent to the first shot area in a second direction perpendicular to the first direction of the surface;
a fourth shot area adjacent to the second shot area in the first direction of the surface and adjacent to the third shot area in the second direction of the surface; and
a space provided among the first to fourth shot areas, and
the method, further comprising:
pressing the template against a first imprint material layer formed in the first shot area so that the first face and the second face overlap the first shot area, bringing the pattern surface into contact with the first imprint material layer, and separating the template after the first imprint material layer is cured;
pressing the template against a second imprint material layer formed in the second shot area so that the first face and the third face overlap the space, bringing the pattern surface into contact with the second imprint material layer, and curing the second imprint material layer and then separating the template;
pressing the template against a third imprint material layer formed in the third shot area so that the second face and the fourth face overlap the space, bringing the pattern surface into contact with the third imprint material layer, and separating the template after the third imprint material layer is cured; and
pressing the template against a fourth imprint material layer formed in the fourth shot area so that the fifth face overlaps the space, bringing the pattern surface into contact with the fourth imprint material layer, and separating the template after the fourth imprint material layer is cured.

8. The imprint method according to claim 6, wherein
a height of the first face and a height of the second face are the same as a height of the uppermost face, and
a height of the third face and a height of the fourth face are the same as a height of a lowermost face of the pattern surface.

9. The imprint method according to claim 6, wherein
the first height and the second height is smaller than a height of a lowermost face of the pattern surface relative to the uppermost face, and
the third height and the fourth height is greater than the height of the lowermost face of the pattern surface relative to the uppermost face.

10. The imprint method according to claim 6, wherein
the fifth face is provided outside the fourth face.

11. The imprint method according to claim 7, wherein
the first end has a first depressed portion that depresses toward inside the mesa along the second direction,
the second end has a second depressed portion that depresses toward inside the mesa along the first direction,
the third end has a first protruding portion that is provided opposite the first depressed portion and protrudes toward outside the mesa along the second direction,
the fourth end has a second protruding portion that is provided opposite the second depressed portion and protrudes toward outside the mesa along the first direction and a third protruding portion that protrudes toward outside the mesa along the first direction, and
the fifth face is provided at the third protruding portion.

12. A method of manufacturing a semiconductor device comprising:
forming an etching mask on a surface of an object, the etching mask having a pattern, and the object including a semiconductor substrate, and
etching the object using the etching mask, wherein
the etching mask is formed by an imprint method using a template,
the template includes a mesa,
the mesa has:
a pattern surface including an imprint pattern;
a first face provided along a first end of the mesa in a first direction, the first face having a first height relative to an uppermost face of the pattern surface;
a second face provided along a second end of the mesa in a second direction perpendicular to the first direction and having a second height relative to the uppermost face;
a third face provided along a third end of the mesa in the second direction, the third end being opposite the second end, and the third face having a third height greater than each of the first height and the second height relative to the uppermost face;
a fourth face provided along a fourth end of the mesa in the first direction, the fourth end being opposite the first end, and the fourth face having a fourth height greater than each of the first height and the second height relative to the uppermost face; and
a fifth face provided along a first corner of the mesa, the first corner being adjacent to each of the third end and the fourth end, and the fifth face having a fifth height greater than each of the third height and the fourth height relative to the uppermost face.

13. The method according to claim 12, wherein
the surface includes:
a first shot area;
a second shot area adjacent to the first shot area in a first direction of the surface;
a third shot area adjacent to the first shot area in a second direction perpendicular to the first direction of the surface;
a fourth shot area adjacent to the second shot area in the first direction of the surface and adjacent to the third shot area in the second direction of the surface; and
a space provided among the first to the fourth shot area, and
the imprint method includes:
pressing the template against a first imprint material layer formed in the first shot area so that the first face and the second face overlap the first shot area, bringing the pattern surface into contact with the first imprint material layer, and separating the template after the first imprint material layer is cured;
pressing the template against a second imprint material layer formed in the second shot area so that the first face and the third face overlap the space, bringing the pattern surface into contact with the second imprint material layer, and separating the template after the second imprint material layer is cured;
pressing the template against a third imprint material layer formed in the third shot area so that the second face and the fourth face overlap the space, bringing the pattern surface into contact with the third imprint material layer, and separating the template after the third imprint material layer is cured; and
pressing the template against a fourth imprint material layer formed in the fourth shot area so that the fifth face overlaps the space, bringing the pattern surface into contact with the fourth imprint material layer, and separating the template after the fourth imprint material layer is cured.

14. The method according to claim 12, wherein
a height of the first face and the second face are the same as a height of the uppermost face, and
a height of the third face and a height of the fourth face are the same as a height of a lowermost face of the pattern surface.

15. The method according to claim 12, wherein
the first height and the second height is smaller than a height of a lowermost face of the pattern surface relative to the uppermost face, and
the third height and the fourth height is greater than the height of the lowermost face of the pattern surface relative to the uppermost face.

16. The method according to claim 12, wherein
the fifth face is provided outside the fourth face.

17. The method according to claim 13, wherein
the first end has a first depressed portion that depresses toward inside the mesa along the second direction,
the second end has a second depressed portion that depresses toward inside the mesa along the first direction,
the third end has a first protruding portion that is provided opposite the first depressed portion and protrudes toward outside the mesa along the second direction,
the fourth end has a second protruding portion that is provided opposite the second depressed portion and protrudes toward outside the mesa along the first direction and a third protruding portion that protrudes toward outside the mesa along the first direction, and
the fifth face is provided at the third protruding portion.

18. The template according to claim 1, wherein
the first face extends along the first end from a second corner of the mesa to a third corner of the mesa, the second corner being adjacent to each of one end of the first end and one end of the third end, and the third corner being adjacent to each of the other end of the first end and the other end of the third end,
the second face extends along the second end from the third corner to a fourth corner of the mesa, the fourth corner being adjacent to each of one end of the second end and one end of the fourth end,
the third face extends along the third end from one end of the first face to one end of the fifth face, and
the fourth face extends along the fourth end from one end of the second face to the other end of the fifth face.

19. The imprint method according to claim 6, wherein
the first face extends along the first end from a second corner of the mesa to a third corner of the mesa, the second corner being adjacent to each of one end of the first end and one end of the third end, and the third corner being adjacent to each of the other end of the first end and the other end of the third end,
the second face extends along the second end from the third corner to a fourth corner of the mesa, the fourth corner being adjacent to each of one end of the second end and one end of the fourth end,
the third face extends along the third end from one end of the first face to one end of the fifth face, and
the fourth face extends along the fourth end from one end of the second face to the other end of the fifth face.

20. The method according to claim 12, wherein
the first face extends along the first end from a second corner of the mesa to a third corner of the mesa, the second corner being adjacent to each of one end of the first end and one end of the third end, and the third corner being adjacent to each of the other end of the first end and the other end of the third end,
the second face extends along the second end from the third corner to a fourth corner of the mesa, the fourth corner being adjacent to each of one end of the second end and one end of the fourth end,
the third face extends along the third end from one end of the first face to one end of the fifth face, and
the fourth face extends along the fourth end from one end of the second face to the other end of the fifth face.
